(19) United States
(12) Patent Application Publication
(10) Pub. No.: US 2012/0139569 A1
(43) Pub. Date: Jun. 7, 2012

(54) CIRCUIT APPARATUS

(75) Inventors: KUO-CHIANG CHEN, TAIPEI COUNTY (TW); YEN-YI CHEN, TAIPEI COUNTY (TW)

(73) Assignee: FORTUNE SEMICONDUCTOR CORPORATION, TAIPEI HSIEN (TW)

(21) Appl. No.: 12/959,641

(22) Filed: Dec. 3, 2010

(51) Int. Cl. G01R 31/3187

(52) U.S. Cl. 324/750.3

(57) ABSTRACT

A circuit apparatus includes an input end, an output end, an enable module, a first function module and a second function module. The enable module couples to the input end for receiving an input voltage and outputs an enable signal while the input voltage falls within a first voltage scope. The first function module couples to the enable module and the output end, and performs a test mode according to the enable signal so as to output a test result to the output end. The second function module couples to the input end for receiving the input voltage via the input end and performs a standard mode while the input voltage falls within a second voltage scope.

### BACKGROUND OF THE INVENTION

1. Field of the Invention

The present invention relates to a circuit apparatus; in particular, to a circuit apparatus enabling internal test function.

2. Description of Related Art

In chip tests, it usually needs to perform analyses on certain internal functions of the chip; however, since the operation of such internal functions may be undefined in the specification of the chip, it is impossible to measure the required internal function from pins of the chip by means of normal test methods.

### SUMMARY OF THE INVENTION

Regarding to the aforementioned issues, the present invention discloses a circuit apparatus enabling internal test function, in which, when a voltage in a particular scope is applied to an input end of the circuit apparatus, the circuit apparatus activates the internal test function. At this moment, the circuit apparatus enters into a test mode and sends in response a test result through an output end thereby allowing a tester to obtain the particular parameter in the circuit apparatus,

According to an embodiment, a circuit apparatus of the present invention comprises an input end, an output end, an enable module, a first function module and a second function module. The enable module is coupled to the input end for receiving an input voltage and outputs an enable signal when the input voltage falls within a first voltage scope. The first function module is coupled to the enable module and the output end, and performs a test mode according to the enable signal thereby outputting a test result to the output end. The second function module is coupled to the input end for receiving the input voltage via the input end and performs a standard mode when the input voltage falls within a second voltage scope.

According to another embodiment, the circuit apparatus of the present invention comprises an input end, a plurality of output ends, an enable module and a function module. The enable module is coupled to the input end for receiving an input voltage and outputs a corresponding enable signal when the input voltage falls within a respective voltage scope. The function module is coupled to the enable module and the plurality of output ends, and performs a corresponding test mode according to the respective enable signal, thereby outputting a corresponding test result to a corresponding output end.

According to yet another embodiment, the enable module of the present invention comprises a plurality of inverters and an encoder, in which the plurality of inverters receive an input voltage and output a first set of logic levels when the input voltage falls within a first voltage scope. The encoder is coupled to the plurality of inverters and a function module for receiving the first set of logic levels, and outputs an enable signal to the function module.

In summary of the above-said descriptions, the circuit apparatus disclosed in the embodiments of the present invention allows to run a standard mode when a voltage out of a particular scope is applied to the input end. In addition, when a voltage within the particular scope is applied to the same input end, the circuit apparatus executes a test mode and outputs a test result through the output end. In this way, a tester can test and analyze with regards to certain internal functions of the circuit apparatus in order to resolve the issue concerning the incapability of tests on the required internal functions from the circuit apparatus under normal measurement operations.

### BRIEF DESCRIPTION OF THE DRAWINGS

FIG. 1 shows a functional block diagram of a circuit apparatus according to a first embodiment of the present invention;

FIG. 2 shows a functional block diagram of an enable module circuit according to the first embodiment of the present invention;

FIG. 3 shows a related chart of the first embodiment of the present invention;

FIG. 4 shows a functional block diagram of a circuit apparatus according to a second embodiment of the present invention;

FIG. 5 shows a functional block diagram of an enable module circuit according to the second embodiment of the present invention;

FIG. 6 shows a related chart of the second embodiment of the present invention; and

FIGS. 7 to 11 show functional block diagrams for the enable module circuit of a variety of different structures according to the present invention.

### DETAILED DESCRIPTION OF THE PREFERRED EMBODIMENTS

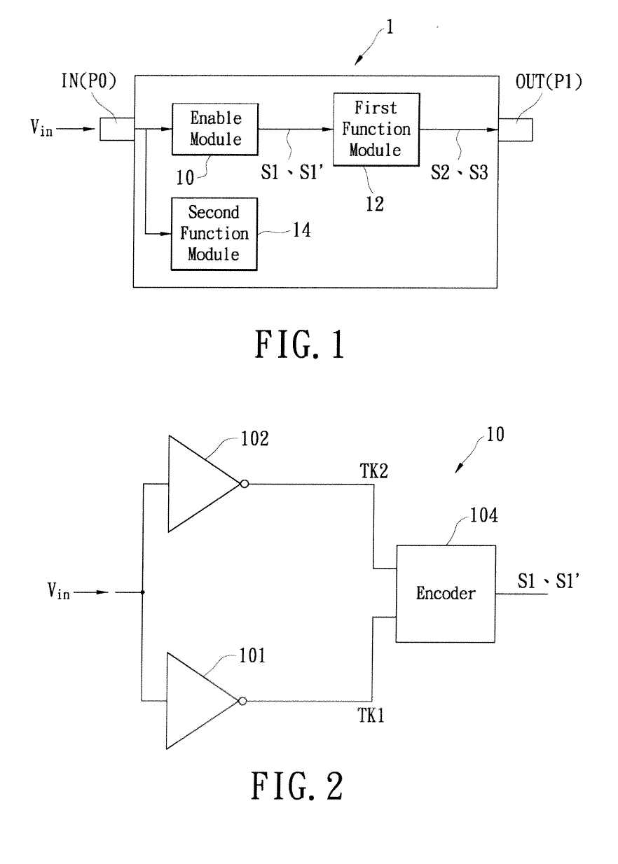

Refer initially to FIG. 1, wherein a functional block diagram of a circuit apparatus according to a first embodiment of the present invention is shown. The circuit apparatus 1 comprises an input end IN, an output end OUT, an enable module 10, a first function module 12, and a second function module 14. The circuit apparatus 1 may be in a form of a chip, or else configured as an integrated circuit (IC) package; in case that the circuit apparatus 1 is configured as an IC package, the input end IN can be an input pin P0 on the IC and the output end OUT can be implemented as an output pin P1 of the IC.

Refer again to FIG. 1. The enable module 10 is coupled to the input end IN for receiving an input voltage Vin via the input end IN, and outputs an enable signal S1 when the received input voltage Vin falls within a first voltage scope Vscop1. The first function module 12 is coupled to the enable module 10 and the output end OUT, which executes a test mode according to the enable signal S1 and sends out a test result S2 to the output end OUT. As described above, the first voltage scope Vscop1 is in between a first preset voltage VTH and a second preset voltage VTL.

Refer once again to FIG. 1. The first function module 12 calculates various parameter values inside the circuit apparatus 1 based on the enable signal S1. In case that the circuit apparatus 1 is a charge circuit chip, the first function module 12 may run the test mode according to the enable signal S1, test the prescribed cut-off charge voltage or cut-off discharge voltage inside the charge circuit chip based on the performance of test mode, and then transfer the test result S2 to the output end OUT.

Refer yet once again to FIG. 1. The second function module 14 is coupled to the input end IN for receiving the input voltage Vin through the input end IN and performs a standard mode while the received input voltage Vin falls within a second voltage scope Vscop2. The aforementioned second voltage scope Vscop2 is not equal to the first voltage scope Vscop1. Besides, the second function module 14 runs the standard mode when the input voltage Vin is within the second voltage scope Vscop2, where the standard mode includes various application functions of the circuit apparatus 1.

Accordingly, when the input voltage Vin received by the input end IN of the circuit apparatus 1 falls within the second voltage scope Vscop2 (i.e., outside of the first preset voltage VTH and the second preset voltage VTL), the second function module 14 is activated thus allowing the circuit apparatus 1 to operate in the standard mode. At this moment, the enable module 10 stops sending the enable signal S1 to the first function module 12, thereby causing the first function module 12 to stop outputting the test result S2 but alternatively outputting an operation status signal S3.

On the other hand, suppose the input voltage Vin received by the input end IN of the circuit apparatus 1 falls within the first voltage scope Vscop1 (i.e., between the first preset voltage VTH and the second preset voltage VTL), the second function module 14 is deactivated and the circuit apparatus 1 now operates in the test mode. At this point, the enable module 10 transfers the enable signal S1 to the first function module 12 to cause the first function module 12 to output the test result S2; meanwhile the output of the operation status signal S3 is halted.

In this way, when an input voltage Vin within the scope of the first preset voltage VTH and the second preset voltage VTL is applied to a single input end IN of the circuit apparatus 1, the circuit apparatus 1 enters into the test mode and sends in response the test result S2 through the output end OUT, thereby allowing the tester to know the particular parameter values inside the circuit apparatus 1.

In conjunction with FIG. 1, reference is now made to FIG. 2, wherein a functional block diagram of an enable module circuit according to the first embodiment of the present invention is shown. The enable module 10 as depicted comprises a plurality of inverters 101, 102 as well as an encoder 104. Herein two inverters 101, 102 are exemplarily illustrated, but the present invention is by no means limited thereto. The enable module 10 essentially uses two inverters 101, 102 of different width/length (W/L) ratios as the design basis for the first voltage scope Vscop1 and the second voltage scope Vscop2. Hence, it is possible to relatively modify the first voltage scope Vscop1 and the second voltage scope Vscop2 by changing W/L ratios of the inverters 101, 102.

Referring again to FIG. 2, these two inverters 101, 102 are conjunctively coupled between the input end IN and the encoder 104, in which the two inverters 101, 102 receive the input voltage Vin and output a first set of logic levels when the input voltage Vin falls within the first voltage scope Vscop1. Additionally, the two inverters 101, 102 output a second set of logic levels when the input voltage Vin is not within the first voltage scope Vscop1 (i.e., within the second voltage scope Vscop2). Meanwhile, the encoder 104 is coupled to the inverters 101, 102 and the first function module 12, which receives the first set of logic levels and outputs the enable signal S1 to the first function module 12.

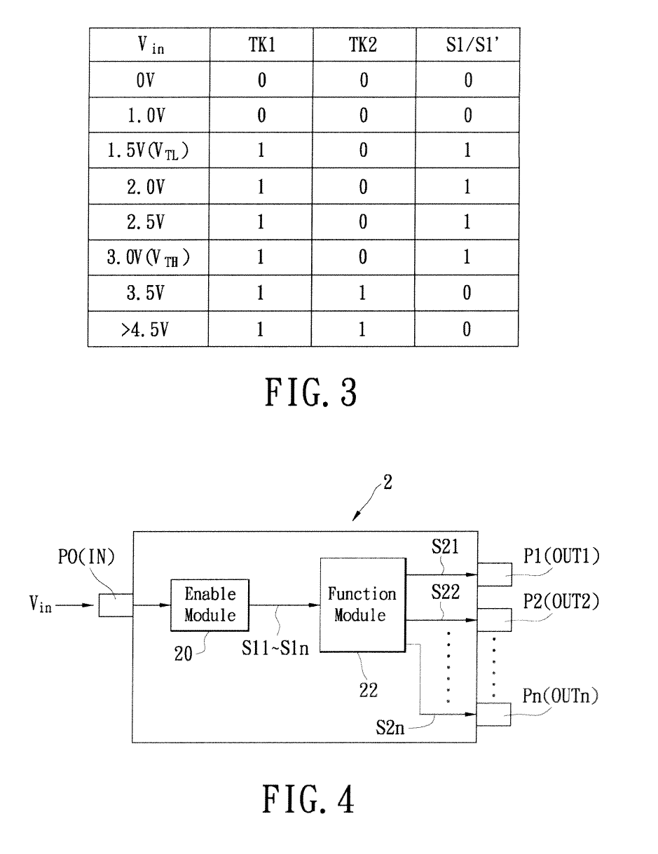

In conjunction with FIG. 3, refer once again to FIG. 2. In the first embodiment, according to the requirement on the output of the enable module 10, the encoder 104 is designed as an exclusive XOR gate, but the present invention is not limited thereto. When the input voltage Vin is in the first voltage scope Vscop1 (the first preset voltage VTH is 3.0V and the second preset voltage VTL is 1.5V), the encoder 104 receives the first set of logic levels from these two inverters 101, 102, as shown in FIG. 3, in which the first set of logic levels include the logic level TK1 having “1” and the logic level TK2 having “0”. After performing XOR logic operations on logic levels TK1 and TK2 by the encoder 104, an enable signal S1 of high level is generated, in which the generated enable signal S1 of high level can be applied to enable the first function module 12 to run the test mode.

It should be noted that in case the input voltage Vin fed to these two inverters 101, 102 is not within the first voltage scope Vscop1, the encoder 104 alternatively receives the second set of logic levels from these two inverters 101, 102, as shown in FIG. 3, in which the second set of logic levels include the logic levels TK1, TK2 of both “0” or the logic levels TK1, TK2 of both At this point, after performing XOR logic operations on logic levels TK1, TK2 by the encoder 104, a disable signal S1′ of low level is generated, in which the generated disable signal S1′ of low level can be applied to disable the first function module 12 to stop performing the test mode.

In summary of the previous descriptions, the circuit apparatus 1 disclosed in the first embodiment receives the input voltage Vin from outside through one single input end IN, runs the test mode when the input voltage Vin falls within the first voltage scope Vscop1, and executes the standard mode when the input voltage Vin is not within the first voltage scope Vscop1. The circuit apparatus 1 performs the test mode so as to send the test result S2 via the output end OUT. Accordingly, a tester can undergo intended tests and analyses with regards to certain functions inside the circuit apparatus 1 in order to resolve the issue concerning the incapability of tests on the required internal functions of the circuit apparatus 1 under normal measurement operations.

Refer next to FIG. 4, wherein a functional block diagram of a circuit apparatus according to a second embodiment of the present invention is shown. The circuit apparatus 2 as depicted comprises an input end IN, a plurality of output ends OUT1˜OUTn, an enable module 20 and a function module 22. Herein the enable module 20 is coupled to the input end IN for receiving an input voltage Vin, and outputs a corresponding enable signal S11˜S1n when the input voltage Vin falls within a respective voltage scope Vscop1˜Vscopn. The function module 22 is coupled to the enable module 20 and a plurality of output ends OUT1˜OUTn, and executes a corresponding test mode based on the respective enable signal S11˜S1n. The function module 22 sends the corresponding test result S21˜S2n to a corresponding output end OUT1˜OUTn in accordance with the performed respective test mode.

Refer again to FIG. 4. The circuit apparatus 2 may be in a form of a chip, or else configured as an integrated circuit (IC) package; in the case that the circuit apparatus 2 is configured as an IC package, the input end IN can be an input pin PO on the IC and the output ends OUT1˜OUTn can be implemented as the output pins P1˜Pn of the IC.

Refer once again to FIG. 4. The function module 22 calculates various parameter values in the circuit apparatus 2 based on the enable signal S11˜S1n. In a case that the circuit apparatus 2 is a charge circuit chip, the function module 22 can run a corresponding test mode according to the respective enable signal S11˜S1n. The function module 22 can test the prescribed cut-off charge voltage or cut-off discharge voltage inside the charge circuit chip based on the execution of the corresponding test mode, and then transfer the corresponding test result S21˜S2n to the respective output end OUT1˜OUTn.

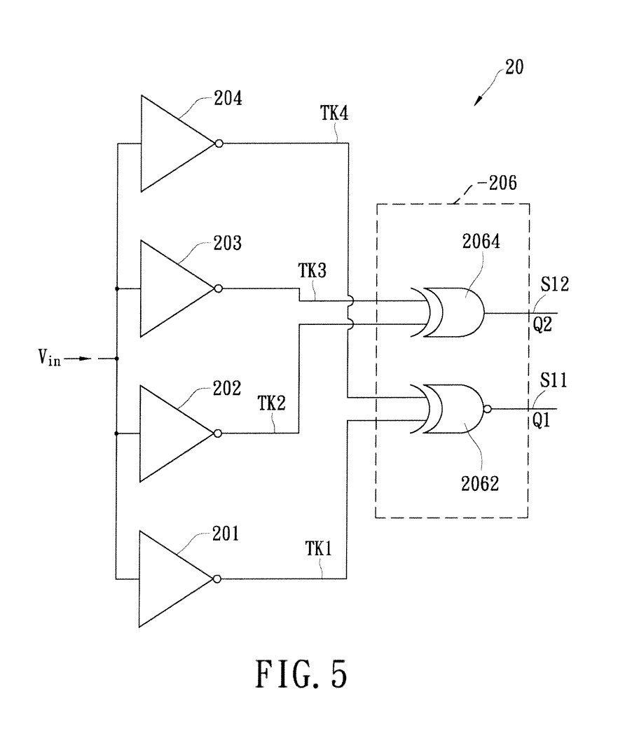

In conjunction with FIG. 4, refer now to FIG. 5, wherein a functional block diagram of an enable module circuit according to the second embodiment of the present invention is shown. The enable module 20 comprises a plurality of inverters 201, 202, 203 and 204 as well as an encoder 206. Herein four inverters 201. 202, 203 and 204 are exemplarily illustrated, but the present invention is by no means limited thereto. These four inverters 201, 202, 203 and 204 are commonly coupled between the input end IN and the encoder 206. Herein these four inverters 201, 202, 203 and 204 generate a corresponding set of logic levels in accordance with the input voltage Vin falling within the respective voltage scope Vscop1˜Vscopn, with each set of logic levels including four logic levels TK1, TK2, TK3 and TK4. Besides, the encoder 206 is coupled to the four inverters 201, 202, 203 and 204 as well as the function module 22 for receiving four logic levels TK1, TK2, TK3 and TK4 in each set of logic levels and outputs the corresponding enable signal S11˜S1n to the function module 22.

Refer yet once again to FIG. 5. In the second embodiment, the enable module 20 has a requirement of two outputs, so the encoder 206 is designed as comprising a XNOR gate 2062 and a XOR gate 2064, but the present invention is by no means limited thereto. Herein the output end of the XNOR gate is used as the first output end Q1 of the enable module 20, and the XOR gate acts as the second output end Q2 of the enable module 20. The encoder 206 performs the XOR logic operation on the logic levels TK2 and TK3 and the XNOR logic operation on the different logic levels TK1 and TK4.

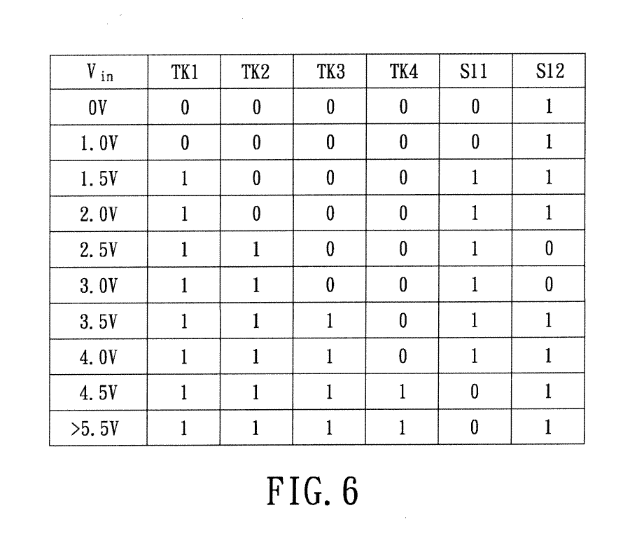

In conjunction with FIG. 5, refer now to FIG. 6, wherein, when the input voltage Vin falls within the voltage scope of 1.5V˜4.0V, the first output end Q1 of the encoder 206 generates an enable signal S11 of high level, in which the enable signal S1 of high level can be used to enable the function module 22, thereby causing it to perform a specific test mode. In addition, when the input voltage Vin falls within the voltage scope of 0V˜2.0V and 3.5V˜5.5V, the second output end Q2 of the encoder 206 generates an enable signal S12 of high level, in which the enable signal S12 of high level can be used to enable the function module 22, thereby causing it to perform another specific test mode.

In summary of the aforementioned descriptions, the circuit apparatus 2 disclosed in the second embodiment receives the input voltage Vin from outside through one single input end IN, runs a corresponding test mode when the input voltage Vin falls within a respective voltage scope Vscop1˜Vscopn, and sends the corresponding test result S21˜S2n via the corresponding output end OUT1˜OUTn. Consequently, a tester can undergo intended tests and analyses with regards to certain functions inside the circuit apparatus 2 in order to resolve the issue concerning the incapability of tests on the required internal functions of the circuit apparatus 2 under normal measurement operations.

It should be noted that the enable module according to the present invention is capable of, based on one single input voltage or multiple sets of input voltages, controlling the number and the delay time of the output signals by means of adjustment on the number and the W/L ratio of the inverters in conjunction with various encoders, thereby further controlling plural sets of test modes.

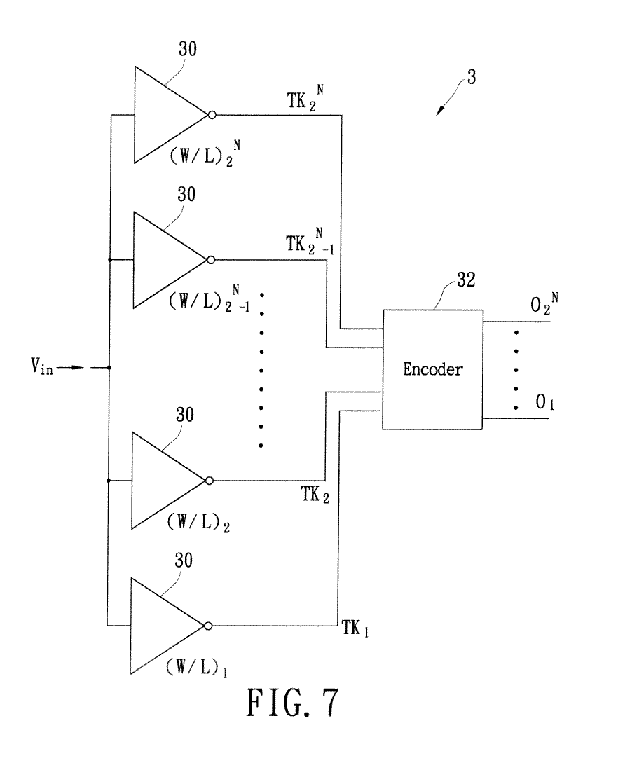

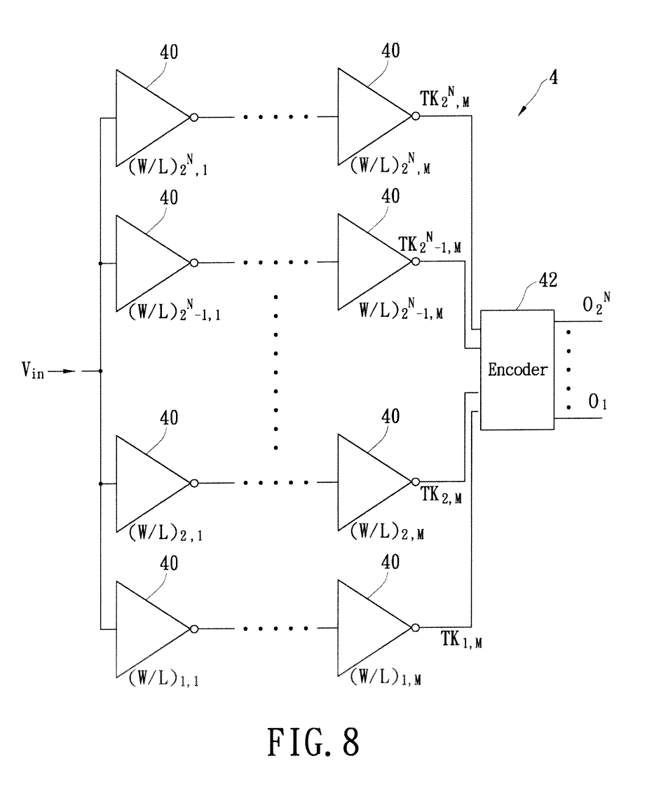

As shown in FIG. 7, the enable module 3 has a single input end and N output ends with N inverters 30 as well as an encoder 32 of N outputs. As shown in FIG. 8, the enable module 4 has a single input end and N output ends with N×M inverters 40 as well as an encoder 42 of N outputs.

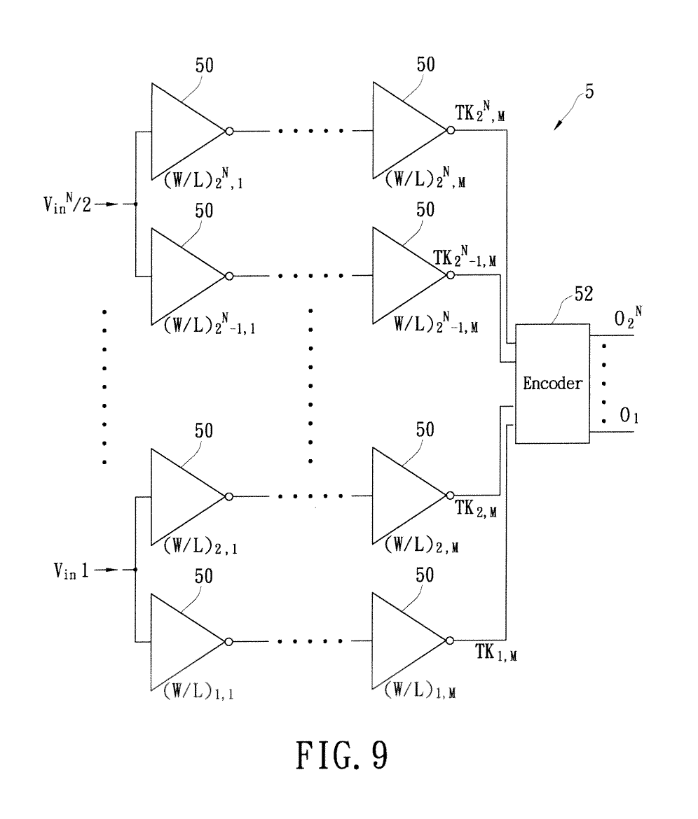

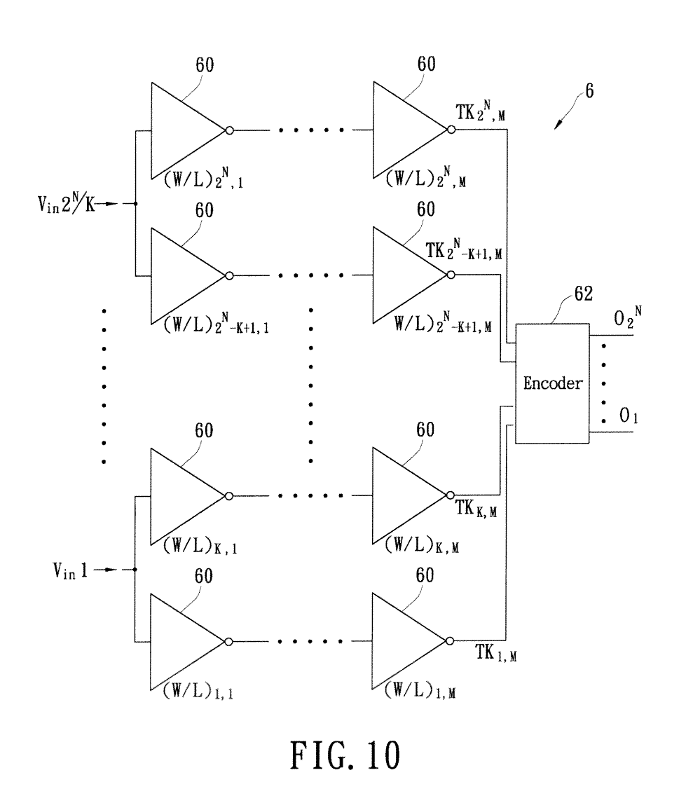

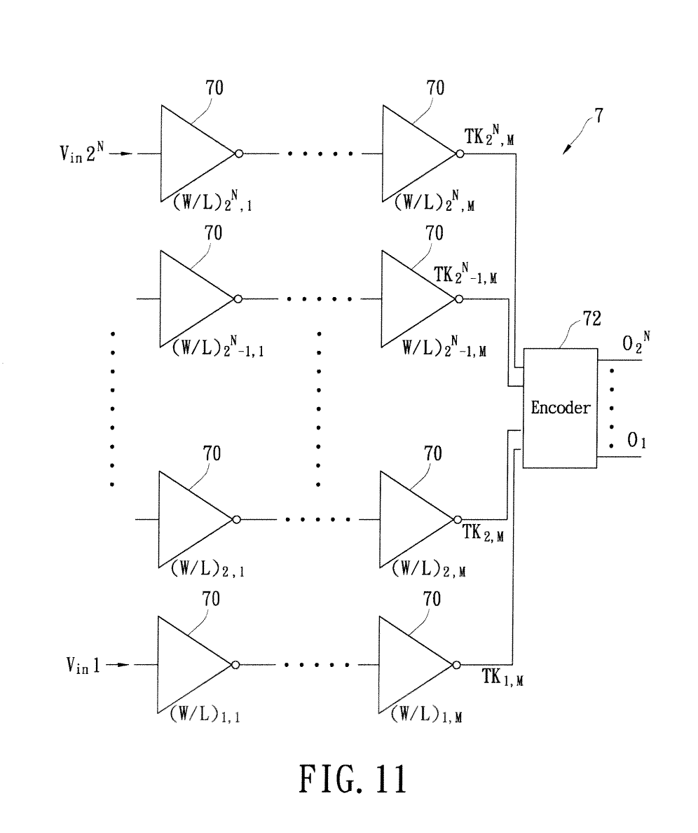

Furthermore, the enable module according to the present invention can also control multiple sets of test modes based on multiple sets of input voltages. As shown in FIG. 9, the enable module 5 has N/2 input ends and N output ends with N×M inverters 50 as well as an encoder 52 of N outputs, in which the input ends of two adjacent inverters 50 commonly receive the same set of input voltage Vin. As shown in FIG. 10, the enable module 6 has 2^{N}/K input ends and N output ends with N×M inverters 60 as well as an encoder 62 of N outputs. Next, as shown in FIG. 11, the enable module 7 has 2^{N} input ends and N output ends with N×M inverters 70 as well as an encoder 72 of N outputs.

In summary of the aforementioned descriptions, the circuit apparatus disclosed in the embodiments of the present invention can perform the standard mode when a voltage outside of a particular scope is applied to the input end. Besides, in a case that a voltage within the particular scope is applied to the same input end, the circuit apparatus performs the test mode and sends the test result through the output end. In this way, a tester is allowed to undergo analyses with regards to certain functions inside the circuit apparatus so as to resolve the issue concerning the incapability of tests on the required internal functions of the circuit apparatus under normal measurement operations.

It should be noted that the descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A circuit apparatus, comprising:
an input end;
an output end;
an enable module, which is coupled to the input end for receiving an input voltage and outputs an enable signal when the input voltage falls within a first voltage scope;
a first function module, which is coupled to the enable module and the output end, and performs a test mode according to the enable signal thereby outputting a test result to the output end; and
a second function module, which is coupled to the input end for receiving the input voltage via the input end and performs a standard mode when the input voltage falls within a second voltage scope.

2. The circuit apparatus according to claim 1, wherein the enable module comprises:
a plurality of inverters, which receive the input voltage, in which the plurality of inverters output a first set of logic levels when the input voltage falls within the first voltage scope; and
an encoder, which is coupled to the plurality of inverters, in which the encoder receives the first set of logic levels and outputs the enable signal to the first function module.

3. The circuit apparatus according to claim 2, wherein the plurality of inverters output a second set of logic levels when the input voltage is out of the first voltage scope, and the encoder receives the second set of logic levels and outputs a disable signal to the first function module.

4. The circuit apparatus according to claim 1, wherein the first voltage scope is between a first preset voltage and a second preset voltage, and the first voltage scope is not equal to the second voltage scope.

5. The circuit apparatus according to claim 1, which is a circuit chip or an integrated circuit, wherein the input end is an input pin of the integrated circuit and the output end is an output pin of the integrated circuit.

6. The circuit apparatus according to claim 1, which is a charge circuit chip, wherein the first function module tests a prescribed cut-off charge voltage or cut-off discharge voltage inside the charge circuit chip based on the enable signal.

7. A circuit apparatus, comprising:
an input end;
a plurality of output ends;
an enable module, which is coupled to the input end for receiving an input voltage and outputs a corresponding enable signal when the input voltage falls within a respective voltage scope; and
a function module, which is coupled to the enable module and the plurality of output ends, and performs a corresponding test mode according to the respective enable signal thereby outputs a corresponding test result to a corresponding output end.

8. The circuit apparatus according to claim 7, wherein the enable module comprises:
a plurality of inverters, which receive the input voltage, in which the plurality of inverters output a corresponding set of logic levels when the input voltage falls within the respective voltage scope; and
an encoder, which is coupled to the plurality of inverters, in which the encoder receives the corresponding set of logic levels and outputs the respective enable signal to the function module.

9. The circuit apparatus according to claim 7, which is a circuit chip or an integrated circuit, wherein the input end is an input pin of the integrated circuit and the plurality of output ends are a plurality of output pins of the integrated circuit.

10. The circuit apparatus according to claim 7, which is a charge circuit chip, wherein the function module tests a prescribed cut-off charge voltage or cut-off discharge voltage inside the charge circuit chip based on the respective enable signal.
